(19) United States
(12) Patent Application Publication
(10) Pub. No.: US 2025/0151299 A1
(43) Pub. Date: May 8, 2025

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventors: Masanori TSUKUDA, Tokyo (JP); Hidenori FUJII, Tokyo (JP); Shinya SONEDA, Tokyo (JP); Kazuya KONISHI, Tokyo (JP); Yasuo KONISHI, Tokyo (JP)

(73) Assignee: Mitsubishi Electric Corporation, Tokyo (JP)

(21) Appl. No.: 18/811,693

(22) Filed: Aug. 21, 2024

(30) Foreign Application Priority Data
Nov. 7, 2023 (JP) 2023-189983

(51) Int. Cl. H01L 29/739; H01L 21/266; H01L 27/088; H01L 29/06; H01L 29/16; H01L 29/20; H01L 29/24; H01L 29/423; H01L 29/66

(52) U.S. Cl. CPC H10D 12/481; H01L 21/266; H10D 12/038; H10D 62/107; H10D 84/83; H10D 62/80; H10D 62/8303; H10D 62/8325; H10D 62/8503; H10D 64/513

(57) ABSTRACT

A first buffer layer and a second buffer layer of a first conductivity type have a higher impurity concentration than a drift layer of the first conductivity type. The first buffer layer is provided in the drift layer. The second buffer layer is provided between a second main surface and the first buffer layer. A separation distance is provided between a location where the first buffer layer has a peak impurity concentration and a location where the second buffer layer has a peak impurity concentration in a thickness direction. The location where the first buffer layer has the peak impurity concentration in the thickness direction has a distribution portion and a non-distribution portion in a plan layout. The non-distribution portion has an effective width smaller than the separation distance. The effective width is twice a farthest distance from the distribution portion in the non-distribution portion in the plan layout.

### BACKGROUND OF THE INVENTION

### Field of the Invention

The present disclosure relates to semiconductor devices and methods of manufacturing the semiconductor devices.

### Description of the Background Art

According to Japanese Patent Application Laid-Open No. 2018-125537, a semiconductor device includes an n-type drift region disposed in a semiconductor substrate and an n-type field stop region formed in a rear surface side of the semiconductor substrate with protons as a donor and having a higher donor concentration than the drift region. Distribution of the concentration of the donor in the field stop region in its depth direction has a plurality of peaks. The plurality of peaks include a first peak and a second peak that is closer to a rear surface of the semiconductor substrate than the first peak is and has a lower concentration than the first peak. First to fourth peaks are shown in drawings as examples of the plurality of peaks in the field stop region. According to Japanese Patent Application Laid-Open No. 2018-125537, in a region from 5/7, as viewed from a front surface of the semiconductor substrate, to the rear surface of the semiconductor substrate, a carrier lifetime is preferably short to reduce a tail current, but an extremely short carrier lifetime can cause an oscillation phenomenon at the time of reverse recovery, so that the carrier lifetime in the region may be shorter than that in a region from 3/7 to 5/7 and be longer than that in a region from the front surface of the semiconductor substrate to 3/7.

According to technology disclosed in Japanese Patent Application Laid-Open No. 2018-125537, distribution of donor concentration in the depth direction (i.e., a thickness direction) of the semiconductor substrate is required to be finely adjusted as described above to sufficiently suppress the oscillation phenomenon (i.e., ringing). Adjustment of distribution of the concentration in the thickness direction is thus complicated. This tends to lead to a significant increase in manufacturing cost of the semiconductor device. In the thickness direction, many impurity peaks each having an optimum concentration are typically required to be formed by proton implantation. This significantly increases an effort in a step of introducing an impurity.

### SUMMARY

The present disclosure has been conceived to solve a problem as described above, and it is an object of the present disclosure to provide a semiconductor device that can easily be manufactured while suppressing ringing.

A semiconductor device according to the present disclosure includes: a drift layer of a first conductivity type provided in a semiconductor substrate having a first main surface and a second main surface opposing the first main surface in a thickness direction; a base layer of a second conductivity type provided between the first main surface of the semiconductor substrate and the drift layer and having a higher impurity concentration than the drift layer; a first buffer layer of the first conductivity type provided in the drift layer and having a higher impurity concentration than the drift layer; and a second buffer layer of the first conductivity type provided between the second main surface of the semiconductor substrate and the first buffer layer and having a higher impurity concentration than the drift layer. A separation distance is provided between a location where the first buffer layer has a peak impurity concentration and a location where the second buffer layer has a peak impurity concentration in the thickness direction. The first buffer layer is selectively formed in a plan layout perpendicular to the thickness direction, so that the location where the first buffer layer has the peak impurity concentration in the thickness direction forms a distribution plane having a distribution portion and a non-distribution portion in the plan layout, the non-distribution portion having an effective width smaller than the separation distance, the effective width being twice a farthest distance from the distribution portion in the non-distribution portion in the plan layout.

According to the present disclosure, the semiconductor device can easily be manufactured while suppressing ringing.

These and other objects, features, aspects and advantages of the present disclosure will become more apparent from the following detailed description when taken in conjunction with the accompanying drawings.

### BRIEF DESCRIPTION OF THE DRAWINGS

FIG. 1 is a schematic top view showing a configuration of a semiconductor device according to Embodiment 1;

FIG. 2 is a schematic partial top view showing a region II of FIG. 1 without illustration of a configuration on a semiconductor substrate;

FIG. 3 is a schematic partial cross-sectional view taken along the line III-III of FIG. 2;

FIG. 4 shows schematic concentration profiles along a line a1-a1, a line a2-a2, and a line b-b of FIG. 3;

FIG. 5 is a schematic diagram showing a plan layout of a first buffer layer of FIG. 3;

FIG. 6 is a schematic partial cross-sectional view showing extension of a leading end of a depletion layer through a non-distribution portion of the first buffer layer of FIG. 5;

FIG. 7 is a graphical representation showing results of simulation on a change in collector-emitter voltage over time at turn-off of an IGBT when a peak impurity concentration of the first buffer layer is 1×10¹⁶/cm³, an effective width of the non-distribution portion of the first buffer layer is 10 μm, a separation distance between the first buffer layer and a second buffer layer in a thickness direction is 5 μm (in a solid line), 10 μm (in a broken line), or 20 μm (in an alternate long and short dashed line);

FIG. 8 is a graphical representation showing results of simulation on a change in collector-emitter voltage over time at turn-off of the IGBT when the effective width of the non-distribution portion of the first buffer layer is 10 μm, the separation distance between the first buffer layer and the second buffer layer in the thickness direction is 20 μm, and the peak impurity concentration of the first buffer layer is 1×10¹⁵/cm³ (in a solid line), 1×10¹⁶/cm³ (in a broken line), or 1×10¹⁷/cm³ (in an alternate long and short dashed line);

FIG. 9 is a schematic partial cross-sectional view showing a step of a method of manufacturing the semiconductor device according to Embodiment 1;

FIG. 10 is a schematic diagram showing a plan layout of the first buffer layer according to Embodiment 2;

FIG. 11 is a schematic diagram showing a plan layout of the first buffer layer according to Embodiment 3;

FIG. 12 is a schematic diagram showing a plan layout of the first buffer layer according to Embodiment 4;

FIG. 13 is a schematic partial cross-sectional view showing a configuration of a semiconductor device according to Embodiment 5;

FIG. 14 is a schematic partial cross-sectional view showing a configuration of a semiconductor device according to Embodiment 6;

FIG. 15 is a schematic partial cross-sectional view showing a configuration of a semiconductor device according to Embodiment 7;

FIG. 16 is a schematic partial cross-sectional view showing a step of a method of manufacturing the semiconductor device according to Embodiment 7; and

FIG. 17 is a schematic partial cross-sectional view showing a modification of FIG. 16.

### DESCRIPTION OF THE PREFERRED EMBODIMENTS

Embodiments will be described below with reference to the drawings. The same or corresponding components bear the same reference signs in the drawings below, and description thereof will not be repeated. Herein, an impurity concentration of an n-type semiconductor is a donor concentration, and an impurity concentration of a p-type semiconductor is an acceptor concentration. A phrase “impurity concentration” refers to a concentration of an activated impurity. A phrase “peak impurity concentration” correspondingly refers to a peak concentration of an activated impurity.

### Embodiment 1

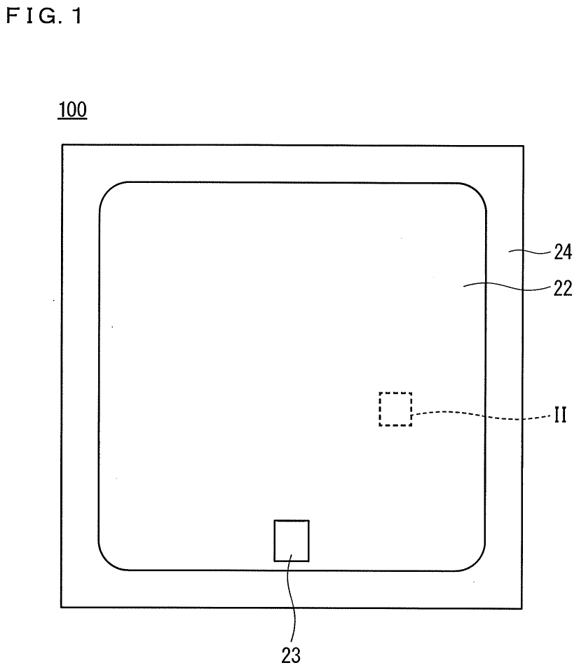

FIG. 1 is a schematic top view showing a configuration of a semiconductor device 100 according to Embodiment 1. The semiconductor device 100 is an insulated gate bipolar transistor (IGBT). The semiconductor device 100 includes a cell portion 22, a gate pad 23 provided in the cell portion 22, and a termination portion 24 disposed around them. The cell portion 22 is a portion in which a main current flows when the semiconductor device 100 is conducting. The gate pad 23 is a portion into which a gate signal to control the main current is to be input. Herein, all the plan layouts described below are those in the cell portion 22 (FIG. 1).

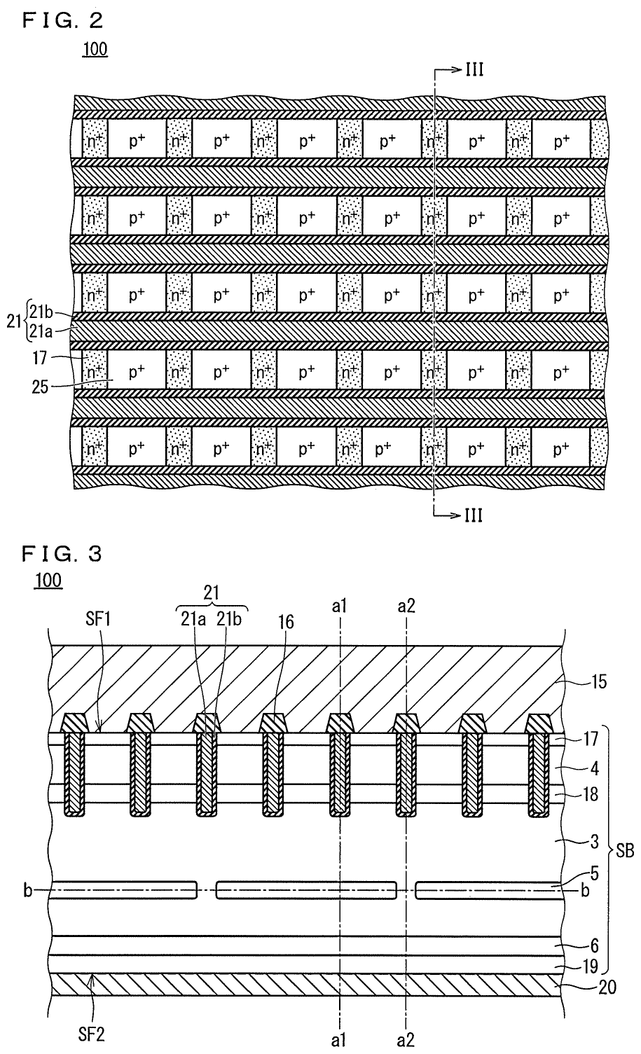

FIG. 2 is a schematic partial top view showing a region II of FIG. 1 without illustration of a configuration on a semiconductor substrate SB (FIG. 3). FIG. 3 is a schematic partial cross-sectional view taken along the line III-III of FIG. 2.

The semiconductor device 100 includes the semiconductor substrate SB having an upper surface SF1 (a first main surface) and a lower surface SF2 (second main surface) opposing the upper surface in a thickness direction. A semiconductor material for the semiconductor substrate SB is Si, SiC, GaN, GaAs, GaO, or diamond, for example.

The semiconductor device 100 includes a pair of main electrodes. Specifically, a main electrode 15 (first main electrode) is provided on the upper surface SF1, and a main electrode 20 (second main electrode) is provided on the lower surface SF2. The semiconductor device 100 is thus configured so that the main current flows in the thickness direction of the semiconductor substrate SB. In other words, the semiconductor device 100 is a vertical semiconductor device. In the present embodiment, the main electrode 15 is an emitter electrode, and the main electrode 20 is a collector electrode. Each of the emitter electrode and the collector electrode may include a silicide layer (not illustrated) in a portion to be in contact with the semiconductor substrate SB to form an ohmic junction with the semiconductor substrate SB.

An n-type (a first conductivity-type) drift layer 3, a p-type (second conductivity-type different from the first conductivity-type) base layer 4, an n-type first buffer layer 5, and an n-type second buffer layer 6 are provided in the semiconductor substrate SB. An n⁺-type source layer 17, an n-type carrier storage layer 18, a p-type collector layer 19, and a p⁺-type contact layer 25 are also provided in the semiconductor substrate SB.

The drift layer 3 is provided between the upper surface SF1 and the lower surface SF2 of the semiconductor substrate SB. The base layer 4 is provided between the upper surface SF1 of the semiconductor substrate SB and the drift layer 3. The first buffer layer 5 is provided in the drift layer 3. The second buffer layer 6 is provided between the lower surface SF2 of the semiconductor substrate SB and the first buffer layer 5. The base layer 4 has a higher impurity concentration than the drift layer 3. The first buffer layer 5 has a higher impurity concentration than the drift layer 3. The second buffer layer 6 has a higher impurity concentration than the drift layer 3.

A trench gate 21 embedded in a trench is provided in the upper surface SF1 of the semiconductor substrate SB. The trench has side walls including portions facing the base layer 4. The trench gate 21 includes a trench electrode 21a and a trench insulating film 21b. The trench insulating film 21b is provided in the upper surface SF1 of the semiconductor substrate SB. The trench electrode 21a faces the base layer 4 via the trench insulating film 21b.

An interlayer insulating film 16 separates the trench electrode 21a and the main electrode 15 from each other. On the other hand, the interlayer insulating film 16 has been patterned so that the main electrode 15 is in contact with the n⁺-type source layer 17 and the p⁺-type contact layer 25.

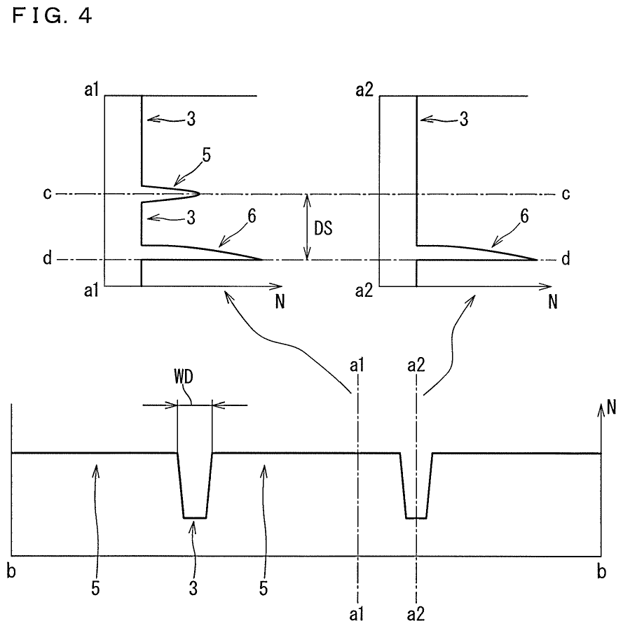

FIG. 4 is graphical representations showing schematic profiles of an impurity concentration N along a line a1-a1, a line a2-a2, and a line b-b of FIG. 3. A separation distance DS is provided between a location where the first buffer layer 5 has a peak impurity concentration and a location where the second buffer layer 6 has a peak impurity concentration in the thickness direction. A set of locations where the first buffer layer 5 has the peak impurity concentration in the thickness direction may substantially form a plane perpendicular to the thickness direction. A set of locations where the second buffer layer 6 has the peak impurity concentration in the thickness direction may substantially form a plane perpendicular to the thickness direction. The peak impurity concentration of the first buffer layer 5 (see FIG. 4) is preferably 1.0×10¹⁶/cm³ or more and is more preferably 1.0×10¹⁷/cm³ or more.

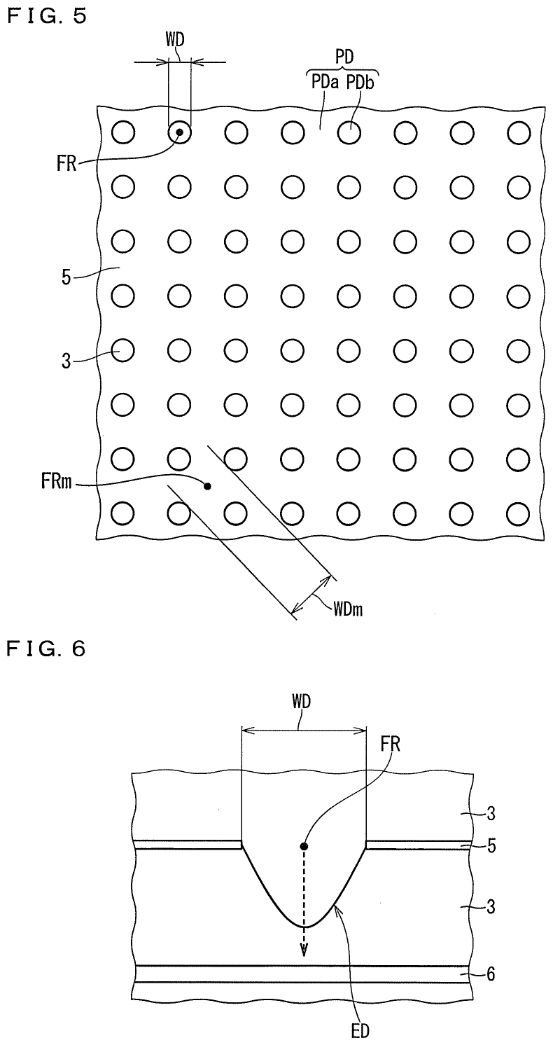

FIG. 5 is a schematic diagram showing a plan layout of the first buffer layer 5 of FIG. 3. The first buffer layer 5 is selectively formed in the plan layout perpendicular to the thickness direction, so that the location where the first buffer layer 5 has the peak impurity concentration in the thickness direction (see FIG. 4) forms a distribution plane PD having a distribution portion PDa and non-distribution portions PDb in the plan layout. The non-distribution portions PDb are portions where the peak impurity concentration of the first buffer layer 5 in the thickness direction is not observed while the peak impurity concentration of the second buffer layer 6 is observed in the plan layout (see the concentration profile along the line a2-a2 shown at the top right of FIG. 4). The distribution portion PDa preferably occupies 5% or more and 90% or less of the area of the distribution plane PD of the peak impurity concentration of the first buffer layer 5.

The non-distribution portions PDb each have an effective width WD smaller than the separation distance DS. That is to say, an inequality WD<DS holds true. The effective width WD is twice a farthest distance from the distribution portion PDa in each of the non-distribution portions PDb in the plan layout. The farthest distance is a distance between the distribution portion PDa and a farthest location FR from the distribution portion PDa in each of the non-distribution portions PDb.

In the plan layout of FIG. 5, the non-distribution portions PDb are each circular, and the farthest location FR corresponds to the center of the circle. Thus, in this plan layout, the farthest distance corresponds to a radius of the circle, and the effective width WD corresponds to a diameter of the circle. A plan layout obtained by interchanging the distribution portion PDa and the non-distribution portions PDb shown in FIG. 5 may be applied as a modification. The plan layout according to the modification has a farthest location FRm and an effective width WDm.

FIG. 6 is a schematic partial cross-sectional view showing extension of a leading end ED of a depletion layer through the non-distribution portions PDb (FIG. 5) of the first buffer layer 5. Extension of the leading end ED of the depletion layer toward the second buffer layer 6 in the thickness direction is most likely to progress in the non-distribution portions PDb. A degree of progress depends greatly on a magnitude of the effective width WD. Specifically, progress of the leading end ED of the depletion layer can be suppressed by reducing the effective width WD.

The first buffer layer 5 is provided for the purpose of obtaining a function to suppress ringing. According to the study conducted by the inventors, the presence of the non-distribution portions PDb does not necessarily significantly impair the function. On the other hand, according to the study conducted by the inventors, reaching the second buffer layer 6 of the leading end ED of the depletion layer leads to the occurrence of ringing. The leading end ED of the depletion layer is thus required to be less likely to reach the second buffer layer 6. The above-mentioned inequality WD<DS holds true due to the need.

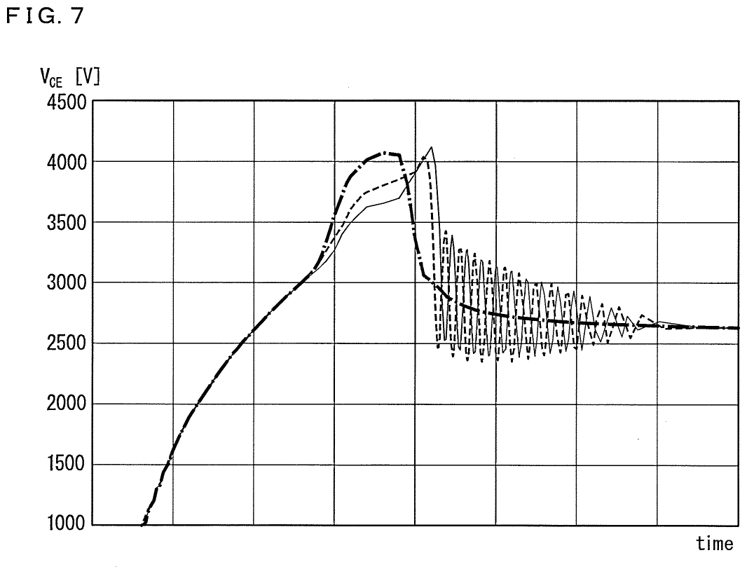

FIG. 7 is a graphical representation showing results of simulation on a change in collector-emitter voltage VCE over time at turn-off of the semiconductor device 100 when the peak impurity concentration of the first buffer layer 5 is 1×10¹⁶/cm³, the effective width WD of each of the non-distribution portions PDb of the first buffer layer 5 is 10 μm, the separation distance DS between the first buffer layer 5 and the second buffer layer 6 in the thickness direction is 5 μm (in a solid line), 10 μm (in a broken line), or 20 μm (in an alternate long and short dashed line). It is found from the results that ringing is prevented in a condition indicated in the alternate long and short dashed line corresponding to the inequality WD<DS.

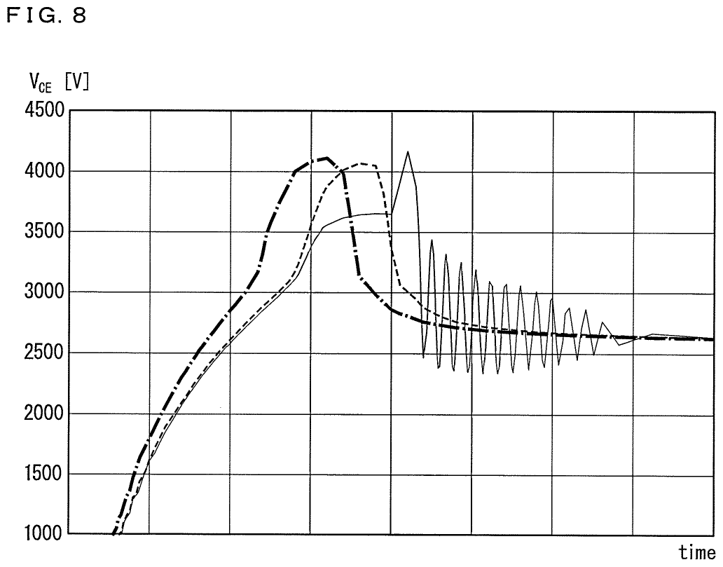

FIG. 8 is a graphical representation showing results of simulation on a change in collector-emitter voltage VCE over time at turn-off of the semiconductor device 100 when the effective width WD of each of the non-distribution portions PDb of the first buffer layer 5 is 10 μm, the separation distance DS between the first buffer layer 5 and the second buffer layer 6 in the thickness direction is 20 μm, and the peak impurity concentration of the first buffer layer 5 is 1×10¹⁵/cm³ (in a solid line), 1×10¹⁶/cm³ (in a broken line), or 1×10¹⁷/cm³ (in an alternate long and short dashed line). According to the results, an effect of suppressing ringing is more pronounced in a condition of a peak impurity concentration of the first buffer layer 5 of 1×10¹⁶/cm³ (in the broken line) than in a condition of a peak impurity concentration of the first buffer layer 5 of 1×10¹⁵/cm³ (in the solid line). The peak impurity concentration of the first buffer layer 5 is thus preferably 1×10¹⁶/cm³ or more and is more preferably ideally 1×10¹⁷/cm³ or more from a standpoint of suppressing ringing.

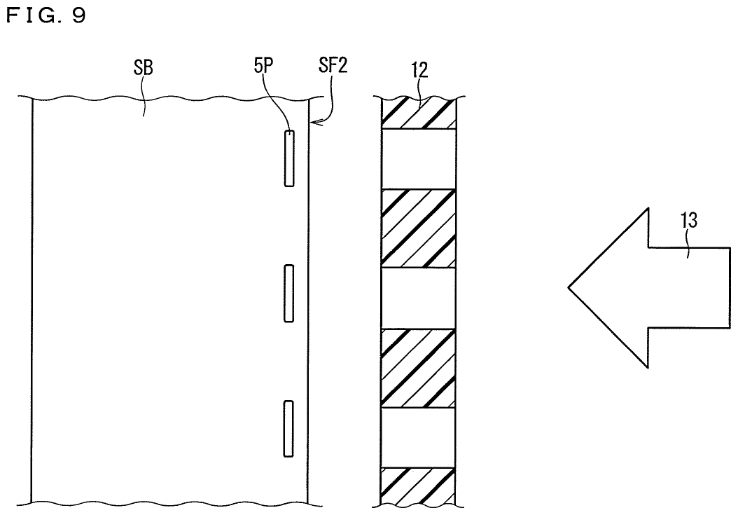

FIG. 9 is a schematic partial cross-sectional view showing a step of a method of manufacturing the semiconductor device 100 according to Embodiment 1. In this step, an impurity is selectively implanted in the plan layout from the lower surface SF2 of the semiconductor substrate SB into the semiconductor substrate SB using an implantation mask 12. In other words, ion implantation is performed using the implantation mask 12. A layer 5P into which the impurity has been implanted is thereby formed in a region in which the first buffer layer 5 (FIG. 3) is to be formed. The implantation mask 12 may be formed using a photoresist. A direction of implantation of the impurity (an arrow 13) may generally include only a single direction. While a space is interposed between the implantation mask 12 and the lower surface SF2 in FIG. 9, the implantation mask 12 may be provided directly on the lower surface SF2. The impurity is then activated by heating the layer 5P to form the first buffer layer 5.

Proton implantation is suitably used as a method of adding the impurity to a relatively deep location. A hydrogen-induced donor can be formed by heating implanted protons, and, in this case, the first buffer layer 5 has the hydrogen-induced donor. Specifically, the distribution portion PDa of the first buffer layer 5 has the hydrogen-induced donor. On the other hand, the non-distribution portions PDb of the first buffer layer 5 are not required to have the hydrogen-induced donor. A concentration of the hydrogen-induced donor can be evaluated using a spreading resistance (SR) method, for example.

When the first buffer layer 5 is formed by ion implantation, specifically, proton implantation from the lower surface SF2 as described above, a defect is formed in a region through which protons have passed, and, as a result, a resistance increases in the region. Due to the influence, the drift layer 3 has a higher resistivity between the first buffer layer 5 and the lower surface SF2 than between the first buffer layer 5 and the upper surface SF1.

Normal steps in the manufacture of the IGBT may be applied to steps other than the above-mentioned step, so that description thereof is omitted.

According to the present embodiment, firstly, an effective impurity concentration of the first buffer layer 5 can be adjusted not only by adjusting an actual impurity concentration of the first buffer layer 5 but also by selectively providing the first buffer layer 5 in the plan layout. Ringing is thereby likely to be suppressed without excessively complicating adjustment of the profile of the impurity concentration in the thickness direction. Secondly, in the plan layout, the effective width WD of each of the non-distribution portions PDb of the first buffer layer 5 is smaller than the separation distance DS between the first buffer layer 5 and the second buffer layer 6 in the thickness direction. The depletion layer extending through the non-distribution portions PDb of the first buffer layer 5 is thereby less likely to reach the second buffer layer 6. The occurrence of ringing due to reaching the second buffer layer 6 of the depletion layer is thereby prevented. For these reasons, the semiconductor device can easily be manufactured while suppressing ringing.

The peak impurity concentration of the first buffer layer 5 is preferably 1.0×10¹⁶/cm³ or more. Extension of the depletion layer can thereby more surely be suppressed. The peak impurity concentration of the first buffer layer 5 is more preferably 1.0×10¹⁷/cm³ or more. Extension of the depletion layer can thereby more sufficiently be suppressed. When the first buffer layer 5 is formed by implantation of the impurity from the lower surface SF2 of the semiconductor substrate SB, a defect is formed between the lower surface SF2 of the semiconductor substrate SB and the first buffer layer 5 due to the implantation. In the present embodiment, specifically, the defect is formed in the region through which protons have passed in the step of implanting protons. The defect becomes a source of electrons and holes responsible for a leakage current upon application of a high voltage by being included in the depletion layer. From a standpoint of preventing this problem, the impurity concentration of the first buffer layer 5 is preferably set to be high to some extent as described above.

The distribution portion PDa preferably occupies 5% or more of the area of the distribution plane PD of the peak impurity concentration of the first buffer layer 5. A function of the first buffer layer 5 to stop the leading end ED (FIG. 6) of the depletion layer extending from the base layer 4 can thereby more sufficiently be ensured.

The distribution portion PDa may occupy 90% or less of the area of the distribution plane PD of the peak impurity concentration of the first buffer layer 5. Deterioration of electrical characteristics (e.g., an increase in conductive resistance) is thereby likely to be sufficiently avoided.

While description has been made on the semiconductor device 100 as the IGBT in the present embodiment, the semiconductor device may include another element in addition to the IGBT. For example, the semiconductor device is a reverse-conductive insulated gate bipolar transistor (RC-IGBT) when including the IGBT and a freewheeling diode. The semiconductor device may be a transistor different from the IGBT and may be a metal-insulator-semiconductor field-effect transistor (MISFET), for example. The MISFET may be a metal-oxide-semiconductor field-effect transistor (MOSFET).

### Embodiment 2

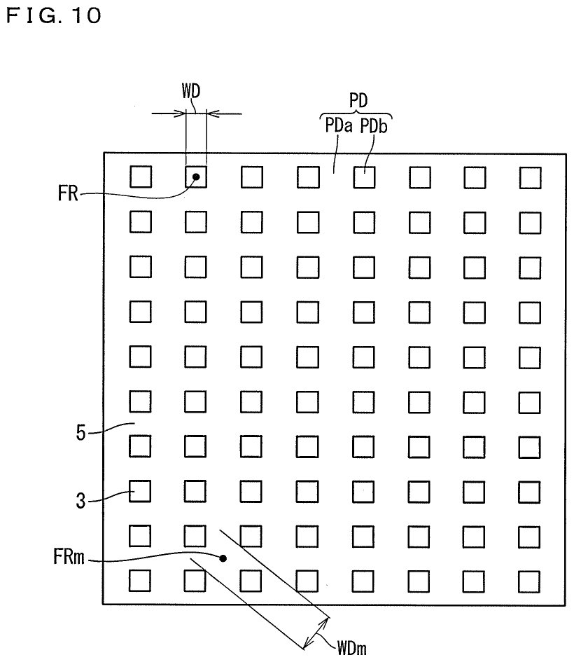

FIG. 10 is a schematic diagram showing a plan layout of the first buffer layer 5 according to Embodiment 2. In Embodiment 2, in contrast to a case of FIG. 5 (Embodiment 1), the non-distribution portions PDb are each square, and the farthest location FR corresponds to the center of the square. Thus, in this plan layout, the farthest distance corresponds to half the length of a side of the square, and the effective width WD corresponds to the length of the side of the square. A rectangle may be used in place of the square, and, in this case, the effective width WD corresponds to the length of a short side. A plan layout obtained by interchanging the distribution portion PDa and the non-distribution portions PDb shown in FIG. 10 may be applied as a modification. The plan layout according to the modification has the farthest location FRm and the effective width WDm. A configuration other than the above-mentioned configuration is substantially the same as the configuration according to Embodiment 1 described above, so that the same or corresponding elements bear the same reference signs, and description thereof will not be repeated.

### Embodiment 3

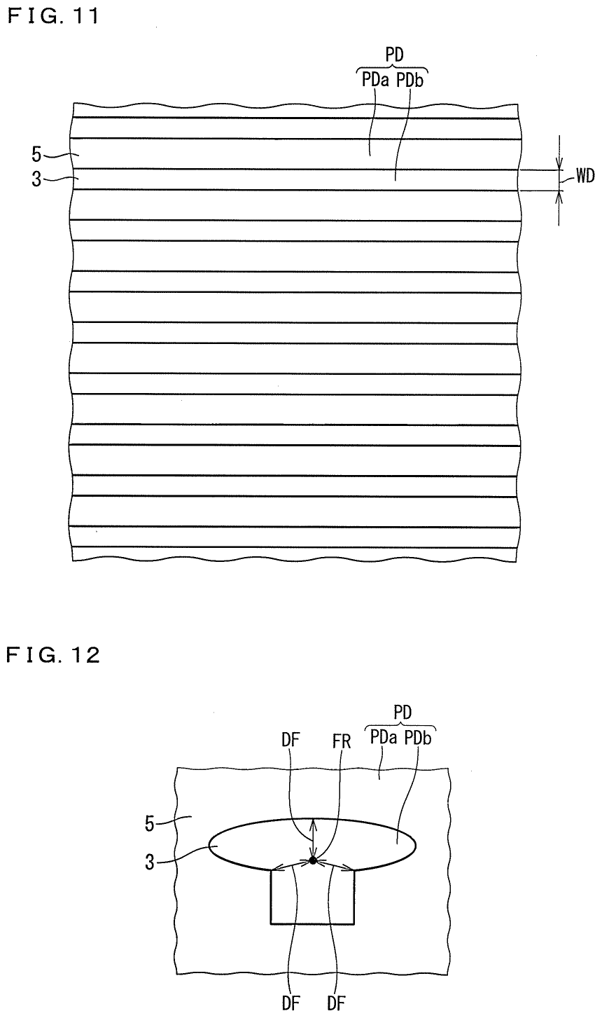

FIG. 11 is a schematic diagram showing a plan layout of the first buffer layer 5 according to Embodiment 3. In Embodiment 3, in contrast to the case of FIG. 5 (Embodiment 1), distribution portions PDa and the non-distribution portions PDb are in stripes. The non-distribution portions PDb are thus each strip shaped, and the farthest location FR corresponds to a straight line (not illustrated) extending along the strip shape at the center of the strip shape. Thus, in this plan layout, the farthest distance corresponds to half the width of the strip shape, and the effective width WD corresponds to the width of the strip shape. A configuration other than the above-mentioned configuration is substantially the same as the configuration according to Embodiment 1 described above, so that the same or corresponding elements bear the same reference signs, and description thereof will not be repeated.

### Embodiment 4

FIG. 12 is a schematic diagram showing a plan layout of the first buffer layer 5 according to Embodiment 4. In Embodiment 4, in contrast to the case of FIG. 5 (Embodiment 1), a non-distribution portion PDb has a complex shape, and the farthest distance DF and the farthest location FR are shown based on the definition described in Embodiment 1 above. A configuration other than the above-mentioned configuration is substantially the same as the configuration according to Embodiment 1 described above, so that the same or corresponding elements bear the same reference signs, and description thereof will not be repeated.

### Embodiment 5

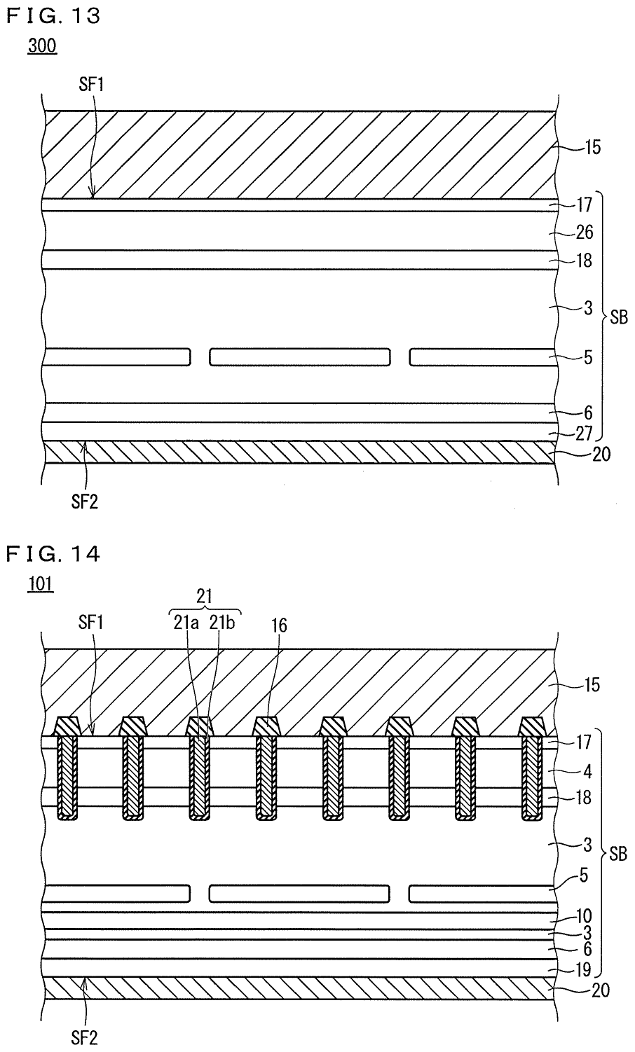

FIG. 13 is a schematic partial cross-sectional view showing a configuration of a semiconductor device 300 according to Embodiment 5. The semiconductor device 300 is a diode in contrast to the semiconductor device 100 (FIG. 3: Embodiment 1). The semiconductor device 300 (FIG. 13) includes a p-type anode layer 26 (a base layer according to the present embodiment) and an n⁺ cathode layer 27 respectively in place of the base layer 4 and the p-type collector layer 19 (FIG. 3). Furthermore, the semiconductor device 300 (FIG. 13) does not require the trench gate 21 and the interlayer insulating film 16 (FIG. 3). A configuration other than the above-mentioned configuration is substantially the same as the configuration according to any of Embodiments 1 to 4 described above, so that the same or corresponding elements bear the same reference signs, and description thereof will not be repeated. According to Embodiment 5, a substantially similar effect to that obtained in any of Embodiments 1 to 4 can be obtained in a case of the diode.

### Embodiment 6

FIG. 14 is a schematic partial cross-sectional view showing a configuration of a semiconductor device 101 according to Embodiment 6. In addition to the configuration of the semiconductor device 100 (FIG. 3), the semiconductor device 101 further includes an n-type third buffer layer 10. The third buffer layer 10 is provided between the first buffer layer 5 and the second buffer layer 6. The third buffer layer 10 has a higher impurity concentration than the drift layer 3. A configuration other than the above-mentioned configuration is substantially the same as the configuration according to any of Embodiments 1 to 3 described above, so that the same or corresponding elements bear the same reference signs, and description thereof will not be repeated. The third buffer layer 10 according to the present embodiment may be applied to the semiconductor device 300 according to Embodiment 4. According to the present embodiment, the effect of suppressing ringing can further be enhanced.

### Embodiment 7

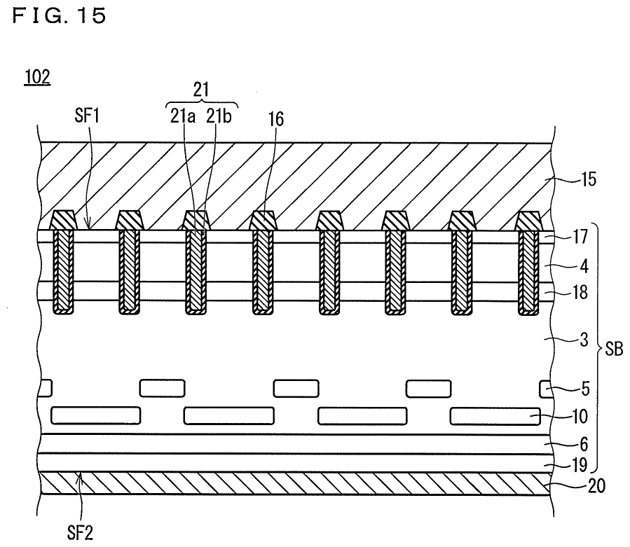

FIG. 15 is a schematic partial cross-sectional view showing a configuration of a semiconductor device 102 according to Embodiment 7. In the semiconductor device 102 (FIG. 15), the third buffer layer 10 is selectively formed in the plan layout in contrast to the semiconductor device 101 (FIG. 14: Embodiment 6). A location where the third buffer layer 10 has a peak impurity concentration in the thickness direction thus forms a distribution plane having distribution portions and a non-distribution portion in the plan layout. In the plan layout, the distribution portions of the third buffer layer 10 overlap the non-distribution portions PDb of the first buffer layer 5, and the non-distribution portion of the third buffer layer 10 overlaps the distribution portion PDa of the first buffer layer 5. In the plan layout, the distribution portions of the third buffer layer 10 preferably have a larger area than the distribution portion PDa of the first buffer layer 5.

In an example shown in FIG. 15, in the plan layout, the distribution portion PDa of the first buffer layer 5 and the non-distribution portion of the third buffer layer 10 are generally the same, and the non-distribution portions PDb of the first buffer layer 5 and the distribution portions of the third buffer layer 10 are generally the same. In other words, a pattern of the distribution plane of the third buffer layer 10 corresponds to a pattern obtained by generally inverting the pattern of the distribution plane PD of the first buffer layer 5.

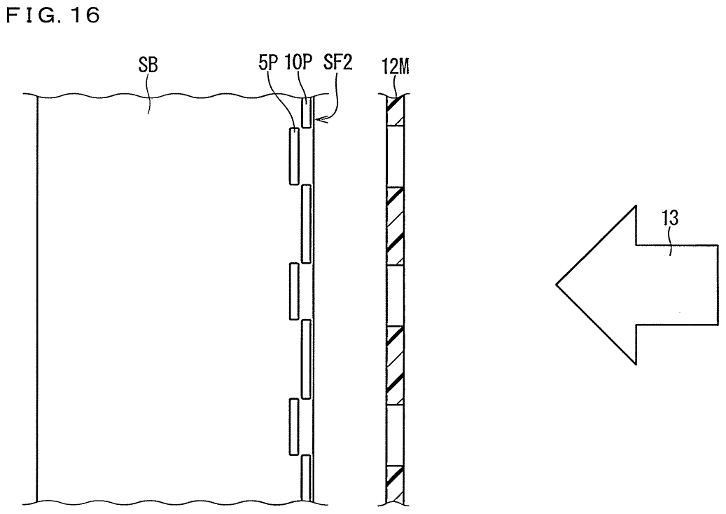

FIG. 16 is a schematic partial cross-sectional view showing a step of a method of manufacturing the semiconductor device 102. In this step, a sufficiently thin implantation mask 12M or a sufficiently high accelerating voltage is used to implant the impurity from the lower surface SF2 of the semiconductor substrate SB into the semiconductor substrate SB simultaneously through an opening of the implantation mask 12M and through a non-opening portion of the implantation mask 12M to attenuate an implantation energy. Specifically, the layer 5P and a layer 10P into each of which the impurity has been implanted are formed in regions in which the first buffer layer 5 and the third buffer layer 10 (FIG. 15) are respectively to be formed. A direction of implantation of the impurity (the arrow 13) may generally include only a single direction. The implantation mask 12M may be formed using a photoresist. While a space is interposed between the implantation mask 12M and the lower surface SF2 in FIG. 16, the implantation mask 12M may be provided directly on the lower surface SF2. The impurity is then activated by heating the layer 5P and the layer 10P to form the first buffer layer 5 and the third buffer layer 10.

Proton implantation is suitably used as the method of adding the impurity to the relatively deep location. The hydrogen-induced donor can be formed by heating implanted protons, and, in this case, the first buffer layer 5 and the third buffer layer 10 have the hydrogen-induced donor.

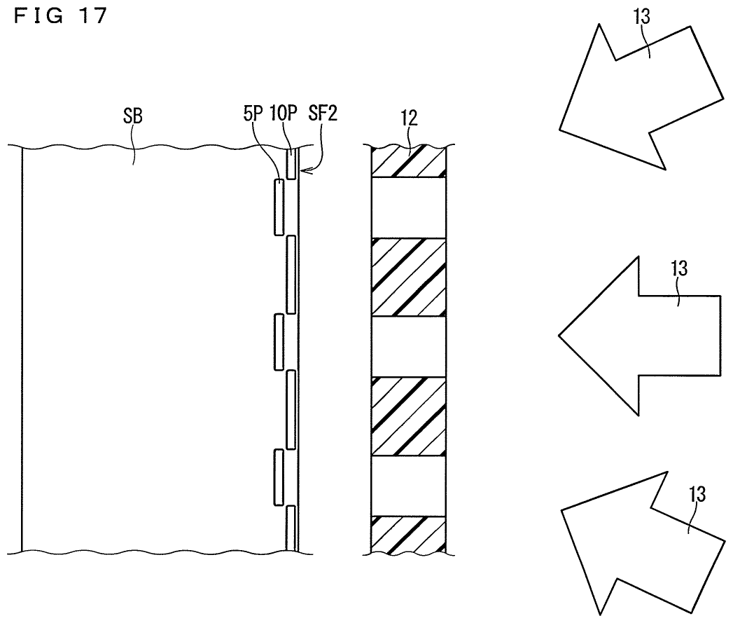

FIG. 17 is a schematic partial cross-sectional view showing a modification of FIG. 16. In the present modification, the impurity is implanted by changing the direction of implantation of the impurity (the arrow 13) while using the implantation mask 12. In other words, the impurity is implanted by changing an angle of implantation while using the same implantation mask 12. In an example shown in FIG. 17, the layer 5P is formed by implantation in a direction substantially perpendicular to the lower surface SF2, and the layer 10P is formed by implantation in an oblique direction relative to the lower surface SF2.

A configuration other than the above-mentioned configuration is substantially the same as the configuration according to Embodiment 6 described above, so that the same or corresponding elements bear the same reference signs, and description thereof will not be repeated. The third buffer layer 10 according to the present embodiment may be applied to the semiconductor device 300 according to Embodiment 4.

According to the present embodiment, two buffer layers, that is, the first buffer layer 5 and the third buffer layer 10 can be formed using a single implantation mask while providing different distributions thereto. In contrast to Embodiment 6 described above, in Embodiment 7, the third buffer layer 10 is also selectively formed in the plan layout, so that an effective concentration of the third buffer layer 10 can be adjusted.

In the plan layout, the distribution portions of the third buffer layer 10 preferably have a larger area than the distribution portion PDa of the first buffer layer 5. The third buffer layer 10 can thus have a higher effective concentration than the first buffer layer 5. A configuration in which an effective impurity concentration has been increased from the base layer 4 to the second buffer layer 6 in a direction of extension of the depletion layer can easily be obtained, and extension of the depletion layer can thereby gently be stopped. The effect of suppressing ringing is thus further enhanced. The third buffer layer 10 only partially formed in the plan layout also contributes to the gentle stop of extension of the depletion layer.

While a case where the semiconductor device is the IGBT or the diode has been described in detail in each of Embodiments 1 to 7 above, the semiconductor device is not limited to them. While a case where the first conductivity type is an n type, and the second conductivity type is a p type has been described in detail, the first conductivity may be the p type, and the second conductivity type may be the n type in a semiconductor device that operates even when the conductivity types are interchanged.

Embodiments can freely be combined with each other and can be modified and omitted as appropriate.

### APPENDICES

Various aspects of the present disclosure will collectively be described below as appendices.

### Appendix 1

A semiconductor device (100-102, 300) comprising:
a drift layer (3) of a first conductivity type provided in a semiconductor substrate (SB) having a first main surface (SF1) and a second main surface (SF2) opposing the first main surface (SF1) in a thickness direction;
a base layer (4) of a second conductivity type provided between the first main surface (SF1) of the semiconductor substrate (SB) and the drift layer (3) and having a higher impurity concentration than the drift layer (3);
a first buffer layer (5) of the first conductivity type provided in the drift layer (3) and having a higher impurity concentration than the drift layer (3); and
a second buffer layer (6) of the first conductivity type provided between the second main surface (SF2) of the semiconductor substrate (SB) and the first buffer layer (5) and having a higher impurity concentration than the drift layer (3), wherein
a separation distance (DS) is provided between a location where the first buffer layer (5) has a peak impurity concentration and a location where the second buffer layer (6) has a peak impurity concentration in the thickness direction, and
the first buffer layer (5) is selectively formed in a plan layout perpendicular to the thickness direction, so that the location where the first buffer layer (5) has the peak impurity concentration in the thickness direction forms a distribution plane (PD) having a distribution portion (PDa) and a non-distribution portion (PDb) in the plan layout, the non-distribution portion (PDb) having an effective width (WD) smaller than the separation distance (DS), the effective width (WD) being twice a farthest distance from the distribution portion (PDa) in the non-distribution portion (PDb) in the plan layout.

### Appendix 2

The semiconductor device (100-102, 300) according to Appendix 1, wherein
the peak impurity concentration of the first buffer layer (5) is 1.0×10¹⁶/cm³ or more.

### Appendix 3

The semiconductor device (100-102, 300) according to Appendix 1 or 2, wherein
the peak impurity concentration of the first buffer layer (5) is 1.0×10¹⁷/cm³ or more.

### Appendix 4

The semiconductor device (100-102, 300) according to any one of Appendices 1 to 3, wherein
the distribution portion (PDa) occupies 5% or more of an area of the distribution plane (PD) of the peak impurity concentration of the first buffer layer (5).

### Appendix 5

The semiconductor device (100-102, 300) according to any one of Appendices 1 to 4, wherein
the distribution portion (PDa) occupies 90% or less of an area of the distribution plane (PD) of the peak impurity concentration of the first buffer layer (5).

### Appendix 6

The semiconductor device (101, 102) according to any one of Appendices 1 to 5, further comprising
a third buffer layer (10) of the first conductivity type provided between the first buffer layer (5) and the second buffer layer (6) and having a higher impurity concentration than the drift layer (3).

### Appendix 7

The semiconductor device (102) according to Appendix 6, wherein
the third buffer layer (10) is selectively formed in the plan layout, so that a location where the third buffer layer (10) has a peak impurity concentration in the thickness direction forms a distribution plane having a distribution portion and a non-distribution portion in the plan layout, and
in the plan layout, the distribution portion of the third buffer layer (10) overlaps the non-distribution portion (PDb) of the first buffer layer (5), and the non-distribution portion of the third buffer layer (10) overlaps the distribution portion (PDa) of the first buffer layer (5).

### Appendix 8

The semiconductor device (102) according to Appendix 7, wherein
in the plan layout, the distribution portion of the third buffer layer (10) has a larger area than the distribution portion (PDa) of the first buffer layer (5).

### Appendix 9

The semiconductor device (100-102, 300) according to any one of Appendices 1 to 8, wherein
the drift layer (3) has a higher resistivity between the first buffer layer (5) and the second main surface (SF2) than between the first buffer layer (5) and the first main surface (SF1).

### Appendix 10

The semiconductor device (100-102, 300) according to any one of Appendices 1 to 9, wherein
the first conductivity type is an n type, the second conductivity type is a p type, and the first buffer layer (5) has a hydrogen-induced donor.

### Appendix 11

The semiconductor device (100-102, 300) according to any one of Appendices 1 to 10, wherein
the semiconductor device (100-102, 300) includes an insulated gate bipolar transistor, a metal-insulator-semiconductor field-effect transistor, a diode, or a reverse-conductive insulated gate bipolar transistor.

### Appendix 12

The semiconductor device (100-102, 300) according to any one of Appendices 1 to 11, wherein
a semiconductor material for the semiconductor substrate (SB) is Si, SiC, GaN, GaAs, GaO, or diamond.

### Appendix 13

A method of manufacturing the semiconductor device (100-102, 300) according to any one of Appendices 1 to 12, the method comprising:
selectively implanting an impurity in the plan layout from the second main surface (SF2) of the semiconductor substrate (SB) into the semiconductor substrate (SB) using an implantation mask (12, 12M); and
activating the impurity by heating to form the first buffer layer (5).

### Appendix 14

The method of manufacturing the semiconductor device (100-102, 300) according to Appendix 13, wherein
the implantation mask (12, 12M) is formed using a photoresist.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device comprising:
a drift layer of a first conductivity type provided in a semiconductor substrate having a first main surface and a second main surface opposing the first main surface in a thickness direction;
a base layer of a second conductivity type provided between the first main surface of the semiconductor substrate and the drift layer and having a higher impurity concentration than the drift layer;
a first buffer layer of the first conductivity type provided in the drift layer and having a higher impurity concentration than the drift layer; and
a second buffer layer of the first conductivity type provided between the second main surface of the semiconductor substrate and the first buffer layer and having a higher impurity concentration than the drift layer, wherein
a separation distance is provided between a location where the first buffer layer has a peak impurity concentration and a location where the second buffer layer has a peak impurity concentration in the thickness direction, and
the first buffer layer is selectively formed in a plan layout perpendicular to the thickness direction, so that the location where the first buffer layer has the peak impurity concentration in the thickness direction forms a distribution plane having a distribution portion and a non-distribution portion in the plan layout, the non-distribution portion having an effective width smaller than the separation distance, the effective width being twice a farthest distance from the distribution portion in the non-distribution portion in the plan layout.

2. The semiconductor device according to claim 1, wherein
the peak impurity concentration of the first buffer layer is 1.0×10¹⁶/cm³ or more.

3. The semiconductor device according to claim 1, wherein
the peak impurity concentration of the first buffer layer is 1.0×10¹⁷/cm³ or more.

4. The semiconductor device according to claim 1, wherein
the distribution portion occupies 5% or more of an area of the distribution plane of the peak impurity concentration of the first buffer layer.

5. The semiconductor device according to claim 1, wherein
the distribution portion occupies 90% or less of an area of the distribution plane of the peak impurity concentration of the first buffer layer.

6. The semiconductor device according to claim 1, further comprising
a third buffer layer of the first conductivity type provided between the first buffer layer and the second buffer layer and having a higher impurity concentration than the drift layer.

7. The semiconductor device according to claim 6, wherein
the third buffer layer is selectively formed in the plan layout, so that a location where the third buffer layer has a peak impurity concentration in the thickness direction forms a distribution plane having a distribution portion and a non-distribution portion in the plan layout, and
in the plan layout, the distribution portion of the third buffer layer overlaps the non-distribution portion of the first buffer layer, and the non-distribution portion of the third buffer layer overlaps the distribution portion of the first buffer layer.

8. The semiconductor device according to claim 7, wherein
in the plan layout, the distribution portion of the third buffer layer has a larger area than the distribution portion of the first buffer layer.

9. The semiconductor device according to claim 1, wherein
the drift layer has a higher resistivity between the first buffer layer and the second main surface than between the first buffer layer and the first main surface.

10. The semiconductor device according to claim 1, wherein
the first conductivity type is an n type, the second conductivity type is a p type, and the first buffer layer has a hydrogen-induced donor.

11. The semiconductor device according to claim 1, wherein
the semiconductor device includes an insulated gate bipolar transistor, a metal-insulator-semiconductor field-effect transistor, a diode, or a reverse-conductive insulated gate bipolar transistor.

12. The semiconductor device according to claim 1, wherein
a semiconductor material for the semiconductor substrate is Si, SiC, GaN, GaAs, GaO, or diamond.

13. A method of manufacturing the semiconductor device according to claim 1, the method comprising:
selectively implanting an impurity in the plan layout from the second main surface of the semiconductor substrate into the semiconductor substrate using an implantation mask; and
activating the impurity by heating to form the first buffer layer.

14. The method of manufacturing the semiconductor device according to claim 13, wherein
the implantation mask is formed using a photoresist.
